(19) United States
(12) Patent Application Publication
(10) Pub. No.: US 2018/0315682 A1
(43) Pub. Date: Nov. 1, 2018

(54) SYSTEMS AND METHODS FOR REINFORCED ADHESIVE BONDING USING TEXTURED SOLDER ELEMENTS

(71) Applicant: GM GLOBAL TECHNOLGY OPERATIONS LLC, Detroit, MI (US)

(72) Inventors: Xin Yang, Shanghai (CN); Dalong Gao, ROCHESTER, MI (US); Blair E. Carlson, ANN ARBOR, MI (US); Yongbing Li, SHANGHAI (CN)

(21) Appl. No.: 15/770,450

(22) PCT Filed: Oct. 21, 2015
(86) PCT No.: PCT/CN2015/092385

§ 371 Date: Apr. 23, 2018

(51) Int. Cl. H01L 23/488; B23K 1/00; B23K 35/36

(52) U.S. Cl. CPC H01L 23/488; B23K 35/3601; B23K 1/0008

(57) ABSTRACT

The present disclosure relates to a bonding system comprising a first substrate, a second substrate, an adhesive, in contact with a first contact surface and a second contact surface, and a plurality of solder elements positioned in the adhesive. Each solder element has a plurality of indentations located on the perimeter of the solder element and the plurality of indentations receiving a portion of the adhesive. Also, the present disclosure relates to a bonding method to produce a solder-reinforced adhesive bond joining a first substrate and a second substrate.

### TECHNICAL FIELD

The present technology relates to adhesive bonding for substrate materials. More specifically, the technology provides interlock in solder-reinforced adhesive bonding between solder elements and an adhesive.

### BACKGROUND

Structural adhesives replace welds and mechanical fasteners in many applications because structural adhesives reduce fatigue and failure commonly found around welds and fasteners. Structural adhesives can also be preferred over welds and mechanical fasteners where resistance to flex and vibration is desired.

When structural adhesives are applied to substrate surfaces, a bond line forms at the meeting of the substrate surfaces. It is critical for optimal performance in these cases for the bond line to have uniform thickness.

When a substantial force is applied, structural adhesives used in adhesive bonding may be loaded (1) normal to the bond line, which can create a peeling effect causing substrate materials to be on different planes (i.e., peel fracture), or (2) perpendicular to the leading edge of a fracture, whether in-plane or out-of-plane, which creates a shearing effect where substrate materials remain on the same plane (i.e., shear fracture). While fracturing is typically avoided, if there is to be fracturing, shear fracture is preferred over peel fracture because shear fracture requires more external loading than peel fracture to produce failure.

Solder material, in the form of solder elements, are added to some structural adhesives to ensure bond line uniformity for adequate bond line control. However, traditional solder elements often have a melting temperature greater than a cure temperature for the adhesive, thus preventing the solder elements from melting before the adhesive cures.

Additionally, the process of producing traditional solder elements can trap impurities within the solder elements, preventing adequate bonding to substrate surfaces. In conventional methods of making solder elements, a solder alloy is drawn out into a solder wire, and the wire is separated into small pieces of solder. These small solder pieces are heated (e.g., using hot oil submersion) to melt the solder material to form conventional solder elements. The balls are then coded (e.g., using cool oil submersion) to solidify the shape of the solder element. This process however allows variation in the weight of each solder element and promotes impurities within the solder elements.

### SUMMARY

A need exists for a structural adhesive that provides interlock between the solder material and adhesive material to inhibit crack propagation or promote propagation along a fracture path requiring an amount of energy greater than a fracture energy needed to propagate a crack directly through a bond line.

In one aspect, the present technology includes a bonding system, comprising a first and second substrate, an adhesive in contact with a first contact surface of the first substrate and a second contact surface of the second substrate, and a plurality of solder elements positioned in the adhesive. Each solder element has a plurality of indentations located on the perimeter of the solder element, and the plurality of indentations receive a portion of the adhesive.

In some embodiments, at least one of the solder elements is in contact with the first contact surface. In some embodiments, at least one of solder elements is in contact with the first contact surface and the second contact surface.

In some embodiments, each of the plurality of solder elements is generally spherical.

In some embodiments, the plurality of solder elements are positioned within the adhesive to inhibit crack propagation or promote crack propagation along a path requiring. In at least one section of the bonding system, an amount of energy that is greater than a fracture energy needed to propagate a crack generally straight through a bond line of the adhesive sans the solder elements.

In some embodiments, the plurality of indentations on each solder element are spaced generally evenly around the perimeter of the solder elements. In some embodiments, the plurality of indentations on at least one of the solder elements are concentrated in one or more areas of the solder element.

In some embodiments, each indentation has a depth that is between 5% and 50% of a solder element length or width.

In some embodiments, the plurality of indentations are formed by passing at least one shaped solder object through a forming channel. The forming channel includes at least one cast having a plurality of protrusions, and the protrusions are impressed on the perimeter of the shaped solder object while the material of the shaped solder object is in a malleable state.

In a further aspect, the present technology includes methods, to produce a solder-reinforced adhesive bond joining a first substrate and a second substrate. The method includes forming a plurality of indentations on a shaped solder object thus forming an indented solder element, where the indentations are located on the perimeter of the solder element. An adhesive is positioned in contact with the first and second substrates, and the indentations of the solder element receive at least a portion of the adhesive. In some embodiments, the indented solder element is positioned to inhibit crack propagation. Heat is applied to the indented solder element by way of at least one of the first and second contact surfaces such that each of the plurality of indented solder elements reaches a solder-element bonding temperature.

In a further aspect, the present technology includes a method, to produce indented solder elements using a forming channel. The method includes using a plurality of protrusions to impress a plurality of shaped solder objects, having malleable material, thus yielding a plurality of indented solder elements. The plurality of indented solder elements is cooled such that the malleable material is hardened. In some embodiments, the forming channel includes at least one cast having the plurality of protrusions in which at least one of the shaped solder objects is received prior to the impressing.

Other aspects of the present technology will be in part apparent and in part pointed out hereinafter.

### DESCRIPTION OF THE DRAWINGS

FIG. 1 illustrates a side view of an exemplary embodiment of a bonding system.

FIG. 2 is a graph illustrating load and displacement of adhesives with (i) with no solder elements, (ii) with solder elements without texture, and (ii) solder elements with texture.

FIG. 3 illustrates an exemplary forming system including a cross-sectional callout of a forming channel used to form of the solder elements of FIG. 1.

The figures are not necessarily to scale and some features may be exaggerated or minimized, such as to show details of particular components. In some instances, well-known components, systems, materials or methods have not been described in detail in order to avoid obscuring the present disclosure. Specific structural and functional details disclosed herein are not to be interpreted as limiting, but merely as a basis for the claims and as a representative basis for teaching one skilled in the art to variously employ the present disclosure.

### DETAILED DESCRIPTION

As required, detailed embodiments of the present disclosure are disclosed herein. The disclosed embodiments are merely examples that may be embodied in various and alternative forms, and combinations thereof. As used herein, for example, exemplary, illustrative, and similar terms, refer expansively to embodiments-that serve as an illustration, specimen, model or pattern.

Descriptions are to be considered broadly, within the spirit of the description. For example, references to connections between any two parts herein are intended to encompass the two parts being connected directly or indirectly to each other. As another example, a single component described herein, such as in connection with one or more functions, is to be interpreted to cover embodiments in which more than one component is used instead to perform the function(s). And vice versa—i.e., descriptions of multiple components described herein in connection with one or more functions are to be interpreted to cover embodiments in which a single component performs the function(s).

In some instances, well-known components, systems, materials, or methods have not been described in detail in order to avoid obscuring the present disclosure. Specific structural and functional details disclosed herein are therefore not to be interpreted as limiting, but merely as a basis for the claims and as a representative basis for teaching one skilled in the art to employ the present disclosure.

The present technology can be used in a wide variety of applications, including in connection with manufacturing components of automobiles, other vehicles, such as marine craft and aircraft, and non-vehicle apparatus.

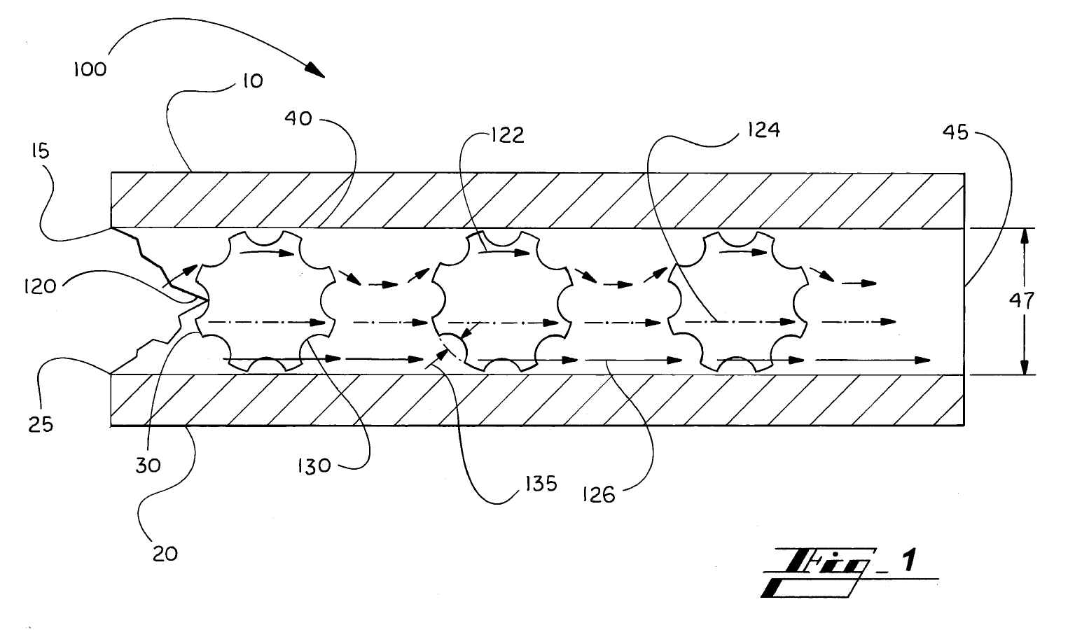

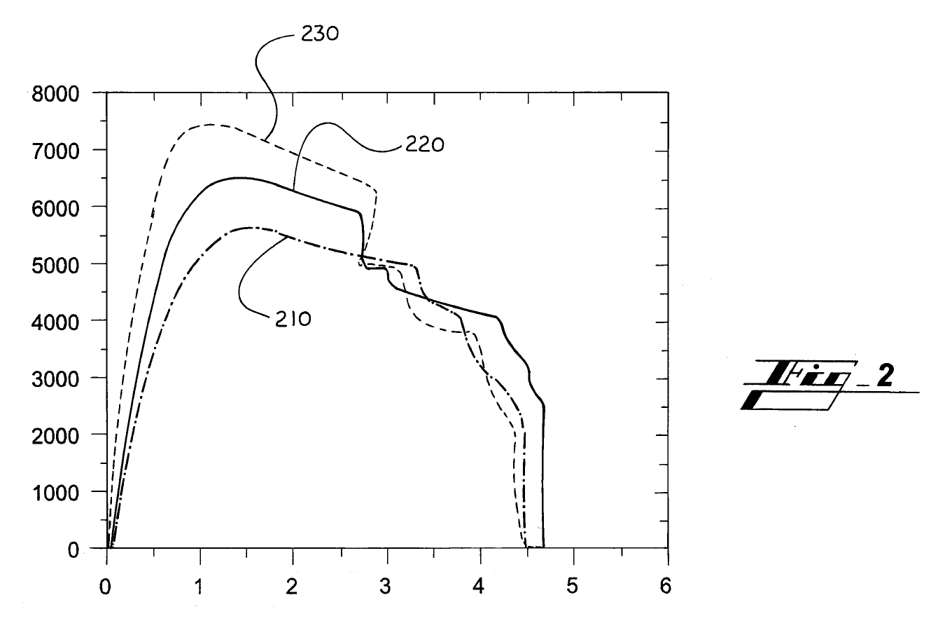

### I. Bonding System—FIGS. 1 and 2

FIG. 1 illustrates a bonding system identified by reference numeral 100. The bonding system 100 includes a structural adhesive 40 and solder elements 30 which are used to join a first substrate 10 to a second substrate 20.

The substrates 10, 20 are the materials that require bonding to one another. The substrates 10, 20 may include the same or different materials. Substrates can include one or more materials such as aluminum, steel, magnesium, composite, or the like.

The adhesive 40 is a structural material used to bond a first contact surface 15 of the first substrate 10 to a second contact surface 25 of the second substrate 20. The adhesive 40 forms a bond line 45 between the contact surfaces 15, 25. In FIG. 1, the bond line 45 extends laterally between the substrates 10, 20 and has a thickness 47.

The solder elements 30 are used in conjunction with the adhesive 40 to form a bridge between the substrates 10, 20. The solder elements 30 can bond to at least one of the substrates 10, 20 during the manufacturing process (e.g., a curing process). The solder elements 30 promote propagation of a developed crack (e.g., crack 120) along one or more fracture paths, such as exemplary fracture paths 122, 124, or 126. As described further below, a crack extending along the fracture path(s) requires more fracture energy than a crack would if extending generally straight through a bond line not having solder elements. The bonding systems 100 of the present technology thus have higher energy-absorption capability. For example, the first fracture path 122 propagates to, through, or around one or more of the solder elements 30, which require higher energy absorption than a crack extending generally straight through the bond line.

The solder elements 30 are in various sized and shaped to contact at least one of the substrates 10, 20. If contact to both of the substrates 10, 20 is desired, the solder elements 30 can be configured to have a dimension approximately equal to or slightly larger than the bond line 46. For contacting only on one of the substrates 10 or 20, the solder elements 30 can be sized slightly smaller than the bond line 45. In a contemplated embodiment, solder elements 30 could be sized so that they might not directly contact either substrate 10, 20 when positioned between them.

The solder elements 30 may include any commercially available material or a custom composition. For example, where at least one of the substrates 10, 20 is at least partially composed of metal and/or metal composites, the solder elements 30 may include materials such as, but not limited to tin (Sn), lead (Pb), and copper (Cu). However, where at least one of the substrates 10, 20 is at least partially composed of polymer and/or a polymer composite, the solder element 30 composition may include polymer materials such as, but not limited to, polycarbonate (PC).

In some embodiments, the solder elements 30 a generally spherical shape, which promotes a more uniform distribution of the solder elements 30 throughout the adhesive 40. However, the solder elements 30 may include other shapes such as, but not limited, to cones, cylinders, rectangles, and the like. In various embodiments, the solder element includes at least one indentation for receiving adhesive 40. The indentations can have any of a wide variety of shapes and sizes, and be referred to by other terms, such as grooves, depressions, voids, and concavities.

Each indentation 130 is positioned at an outer surface of the solder element 30. When multiple indentations are used, they can be distributed in any of a variety of manners, such as generally equally about the surface. Each indentation facilitates interlock between the adhesive 40 and solder element 30.

The indentations 130 create a texture about the perimeter (i.e., the outer surface) of the solder element 30, which improves interlock of the adhesive 40 to the solder element 30. A crack (e.g., crack 120) entering an indentation 130 can either be inhibited (e.g., arrested or prevented from continuing) or propagate along a fracture path that requires a greater amount of fracture energy than it would take to propagate directly through the bond line 45. The path(s) along which the crack is propagated preferably require as much fracture energy as possible for propagation, including potentially a greatest amount. In this way, the indentations 130 promote crack arresting capabilities.

The indentations 130 also increase contact area between the solder elements 30 and the adhesive 40, which improves interlock and wetting. Improved wetting can lead to improved mechanical performance of the bonding system 100 by increasing properties such as, but not limited to peak strength and energy absorption capability.

In some embodiments, the indentations 130 are spaced evenly around the perimeter of the solder element 30. Evenly spaced indentations 130 allow the adhesive to be received around the perimeter of the solder element 30, to improve wetting and promote crack arresting throughout the surface of the solder element 30.

In some embodiments, the indentations 130 may be concentrated In one or more predetermined areas of the solder element 30. Concentrating the indentations 130, may increase a likelihood that the adhesive 40 will be received into areas of the solder element 30 that promote crack inhibiting. The indentations 130 may be concentrated at an area of the solder element 30 that would have the greatest opportunity to receive the adhesive 40 and ultimately a crack (e.g., crack 120).

The indentations 130 can be sized and shaped such that the adhesive 40 can be at least partially received into the indentations 130. Receiving the adhesive 40 into the indentations 130 reduces or prevents any gaps (e.g., air bubbles) that may otherwise form between the solder element 30 and the adhesive 40. The indentations may have has a depth 136 that is between about 5% and about 50% of the solder element length and/or width. For example, where the solder element 30 is a sphere and has a diameter of approximately 0.3 mm, the indentations 130 being hemisphere shape have a depth 135 between about 0.01 mm and about 0.07 mm. The indentations 130 may take on other shapes such as cylinders, rectangles, and the like.

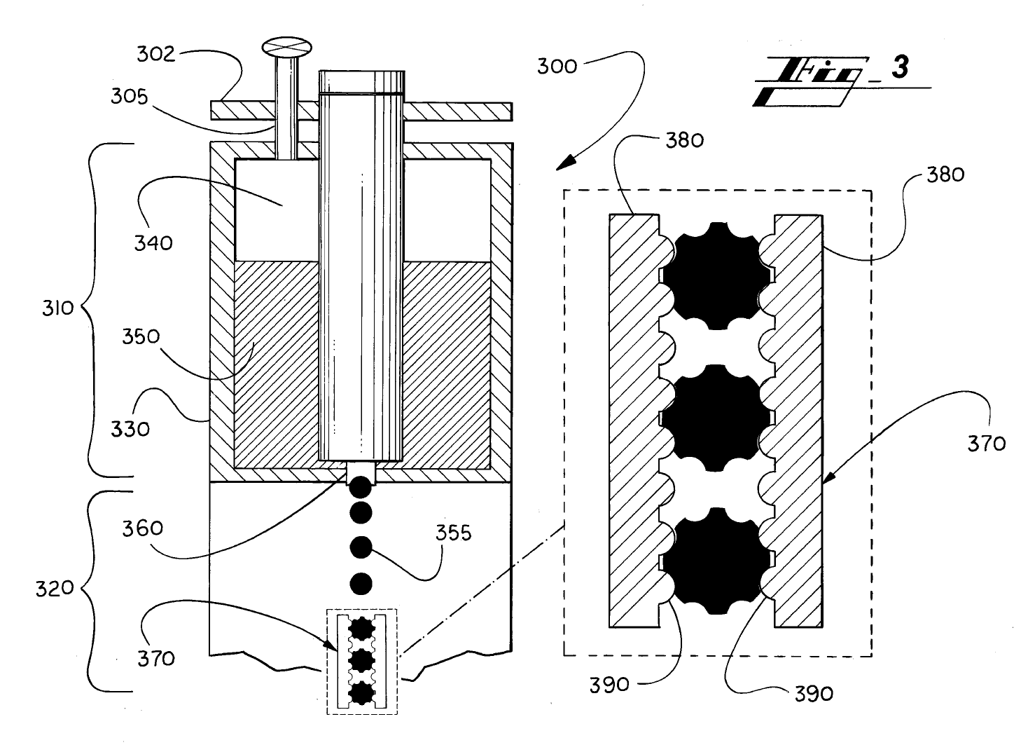

The process of producing the solder elements 30 having indentations 130 is described in greater detail in association with FIG. 3.

The crack 120 may (i) propagate along a first fracture path 122 (depicted as a series of short solid arrows), (ii) propagate along a second fracture path 124 (depicted as a series of dashed arrows), (iii) propagate along a third fracture path 126 (depicted as a series of long solid arrows), or (iv) arrest at an interface of the adhesive 40 and the solder element 30, such as generally where the crack 120 first reaches the solder element 30. Specifically, the crack 120 will first enter the indentation 130 and either arrest or propagate along one or more of the fracture paths 122, 124, 126 that require a greater amount of fracture energy than it would take to propagate directly through the bond line 45. In this way, the indentations 130 promote crack arresting capabilities.

The fracture paths 122, 124, 128 correlate generally to a path of greatest resistance for any fracture. Because the adhesive 40 is generally weaker than the substrates 10, 20 and the solder elements 30, the fracture paths may extend through the adhesive 40 as illustrated by the fracture paths 122, 124 or along one of the contact surfaces as illustrated by the fracture path 126.

The first fracture path 122 is formed when the crack 120 propagates around each solder element 30. Although FIG. 1 depicts the first fracture path 122 extending around each solder element 30 toward the first contact surface 15, alternatively, the first fracture path 122 could extend around any one or more of the solder elements 30 toward the second contact surface 25. Although FIG. 1 depicts the first fracture path 122 as continuing around each subsequent solder element 30, in actuality, when the first fracture path 122 approaches each subsequent solder element 30, the first fracture path 122 may (i) travel around the solder element 30, (ii) travel through the solder element 30, (iii) travel along one of the contact surfaces 15, 25, or (iv) arrest at the interface of the adhesive 40 and the solder element 30.

The second fracture path 124 is formed when the crack 120 propagates through the solder element 30 and then propagates into the adhesive 40 prior to reaching a subsequent solder element 30. Similar to the fracture path 122, when the second fracture path 124, reaches each subsequent solder element 30, the second fracture path 124 may (i) travel around the solder element 30, (ii) travel through the solder element 30, or (iii) travel along one of the contact surfaces 15, 25, or (iv) arrest at the interface of the adhesive 40 and the solder element 30.

The third fracture path 128 is formed when the crack 120 propagates around the solder element 30 and along one of the contact surfaces 15, 25. Unlike the first and second fracture paths 122, 124, when the third fracture path 126 is formed, the crack 120 continues to propagate along the contact surface 15, 25 where the crack 120 commenced.

Alternately, the crack 120 may arrest at any interface of the adhesive 40 and the solder element 30 along the fracture paths 122, 124, 126. Arresting of the crack 120 may be highly desired within the bonding system 100 because reduced or eliminated propagation of the crack 120 may prevent failure of the bonding system 100 due to fracture.

FIG. 2 illustrates load, force (N) [y axis], versus displacement (mm) [x axis], of (i) an adhesive with no solder elements (represented by a first data line 210), (ii) an adhesive containing solder elements without the indentations 130 (represented by a second data line 220), and (ii) an adhesive containing solder elements with the indentations 130 (represented by a third data line 230). Generally, the first data line 210 has a force that is below that of the second and third data lines 220, 230, thus making an adhesive prone to fracture when compared with the adhesives containing solder elements. At varying displacements prior to fracture (e.g., smaller displacement between approximately 0.5 mm and 3.5 mm), the third data line 230 is generally above the second data line 220. Meaning the solder elements 30 that include indentations 130 can withstand a greater force over the same displacement when compared to solder elements without indentations.

### II. Process of Producing Solder Elements—FIG. 3

FIG. 3 illustrates an example forming system 300, which is used to create the indentations 130 on the solder elements 30. The indentations 130 can be formed in a variety of other ways. The illustrated system 300 forms the solder elements 30 using uniform droplet spraying and an indentation process. The forming system 300 includes a tank 330, an orifice 360, and a forming channel 370.

The tank 330 houses a molten solder material 350 which are shaped and formed Into the solder elements 30. The tank 330 forms a first inert environment 310 where the solder material 350 is kept in an inactive atmosphere, for example formed by a gas 340 such as nitrogen (N₂) or argon. The gas 340 is used to avoid unwanted chemical reactions such as oxidation and hydrolysis that occur where there is oxygen and moisture in air that may degrade the solder material 350.

The tank 330 is regulated by a combination of one or more cooling flanges 302 and/or regulators 305. The cooling flange 302 releases excess heat produced by the gas 340 during the melting process of the solder material 350. The regulator 305 allows release of stagnation pressure within the tank 330 as produced by the gas 340 to be regulated.

The solder material 350 is shaped and passed into a second inert environment 320 by way of the orifice 380. The orifice 360, includes one or more outlets for shaping and throughput of solder material 350 at a rate specified by the application. For example, the orifice 360 includes a 3-opening orifice. Additionally, the orifice 360 should be designed such that multiple spheres are not produced together, known as a twin-ball defect. The orifice 360 can mold can be configured to form solder material 350 into any number of shapes such as, but not limited, to spheres, cones, cylinders, rectangles, and the like.

The second inert environment 320 also includes a gas that is used in prevent unwanted chemical reactions during shaping of the solder elements. As the solder material 350 passes through the orifice 360, the solder material 350 Is melded into a desired geometric shape (e.g., sphere) as it enters the second inert environment 320. The second inert environment 320 may contain gas that is similar to the gas 340 in the tank 330. For example, the gas in the second inert environment 320 may be nitrogen or argon gas.

Once the solder material is shaped (referred to as shaped solder object 355), but still warm and formable or malleable, the shaped solder object 355 is passed through the forming channel 370. A cross-sectional view of the forming channel 370 is detailed in the callout of FIG. 3.

The forming channel 370 includes at least one cast 380. The cast 380 includes a plurality of protrusions 390 which are shaped to produce the indentation 130 across the perimeter (i.e., outer surface) of the solder material when impressed on the shaped solder object 355. For example, the protrusions 390 may be shaped as a hemisphere where the desired indentation is half of a sphere. The cast(s) 380 is sized and shaped to receive and position one or more of the shaped solder objects 355 between the cast(s) 380 for indenting by the protrusions 390. For example, the cast(s) 380 opens and allows stacking of the shaped solder objects 355 starting at a bottom surface (not shown). The cast(s) 380 is then closed and then indenting is performed by the protrusions 390.

In operation, the shaped solder object 355 passes through the forming channel 370. Once in the forming channel 370, the cast 380 provides compressional force on the shaped solder object 355 to form the indentations 130, resulting in the solder element 30. In some embodiments, the shaped solder object 355 is roiled along the protrusions 390 to facilitate forming the indentations 130 along with the compressional force.

In some embodiments, the cast 380 includes a first and a second forming plate between which the shaped solder object 355 is passed. One or both of the forming plates can include the protrusions 390. Having forming plates may allow the forming channel 370 to accommodate a predefined throughput volume of the shaped solder objects 355. For example, where the orifice 360 is a 6-opening or 9-opening orifice.

In some embodiments, the first forming plate may be stationary while the second forming plate could translate in a first direction and/or in a second direction (e.g., up and down in the view of FIG. 3), in contact with the surface of the shaped solder object(s) 355, and apply compressional force to the solder material while translating. For example, the shaped solder object 355 is rolled along the protrusions 390 of the first forming plate using compressional and translation force of the second forming plate to generate the indentations 130 on the solder material. In some embodiments, the first and second forming plates translate up/down and/or in/out along the solder material surface. For example, the shaped solder object 355 is rolled along the protrusions 390 of the first and second forming plates using compressional and translational force of both plates.

In some embodiment, the cast 380 is an enclosed fixture where the shaped solder object 355 passes through an opening within the fixture. For example, the cast 380 is a cylinder-shaped fixture including a hollow opening through the center of the cylinder, forming an inner surface. The protrusions 390 are positioned throughout the inner surface to form the indentations 130 on the shaped solder object 355 as it passes through the fixture.

### III. Illustrative Benefits

Many of the benefits and advantages of the present technology are described herein above. The present section presents in summary some of the benefits of the present technology.

The technology creates increased Interlock between the solder element and the adhesive as compared to conventional techniques. Unlike traditional solder elements, which have a generally smooth outer perimeter, textured solder elements have indentations receiving adhesive. Increased interlock between the solder element and adhesive can lead to improved mechanical performance of the bond when compared to conventional techniques.

The technology allows fracture to propagate along a path that requires a greater amount of fracture energy than it would take to propagate directly through the bond line. Using textured solder elements enables a crack to propagate along one of a pre-identified range of fracture paths that require more fracture energy for crack propagation in the adhesive and increases energy-absorption capability of the bonding system.

### IV. Conclusion

Various embodiments of the present disclosure are disclosed herein. The disclosed embodiments are merely examples that may be embodied in various and alternative forms, and combinations thereof.

The law does not require and it is economically prohibitive to illustrate and teach every possible embodiment of the present technology. Hence, the above-described embodiments are merely exemplary illustrations of implementations set forth for a clear understanding of the principles of the disclosure.

Variations, modifications, and combinations may be made to the above-described embodiments without departing from the scope of the claims. All such variations, modifications, and combinations are included herein by the scope of this disclosure and the following claims.

1. A bonding system, comprising:
a first substrate;
a second substrate;
an adhesive, in contact with a first contact surface, of the first substrate, and a second contact surface, of the second substrate; and
a plurality of solder elements positioned in the adhesive, wherein each solder element has a plurality of indentations located on a perimeter of the solder element and the plurality of indentations receiving a portion of the adhesive.

2. The bonding system of claim 1, wherein at least one of the plurality of solder elements is in contact with the first contact surface.

3. The bonding system of claim 1, wherein at least one of the plurality of solder elements is in contact with the first contact surface and the second contact surface.

4. The bonding system of claim 1, wherein each of the plurality of solder elements is generally spherical.

5. The bonding system of claim 1, wherein the plurality of solder elements are positioned within the adhesive to inhibit crack propagation or promote crack propagation along a path requiring, in at least one section of the bonding system, an amount of energy that is greater than a fracture energy needed to propagate a crack generally straight through a bond line of adhesive sans the plurality of solder elements.

6. The bonding system of claim 1, wherein the plurality of indentations on each solder element are spaced generally evenly around the perimeter of the solder element.

7. The bonding system of claim 1, wherein the plurality of indentations on at least one of the solder elements are concentrated in one or more areas of the solder element.

8. The bonding system of claim 7, wherein each indentation has a depth that is between about 5% and about 50% of a solder element length or width.

9. The bonding system of claim 1, wherein the plurality of indentations are formed by passing at least one shaped solder object through a forming channel including at least one cast having a plurality of protrusions, wherein the protrusions are impressed on the perimeter of the shaped solder object while the material of the shaped solder object is in a malleable state.

10. A method, to produce a solder-reinforced adhesive bond joining a first substrate and a second substrate, comprising:
forming, on a perimeter of a shaped solder object, a plurality of indentations, yielding an indented solder element;
positioning an adhesive and the indented solder element between the first substrate and the second substrate with each of the indentations having at least a portion of the adhesive and at least the adhesive contacting the first and second substrates; and
applying heat to the indented solder element by way of at least one of the first and second contact surfaces such that the indented solder element reaches a solder-element bonding temperature.

11. The method of claim 10, wherein the indented solder element is positioned within the adhesive to inhibit crack propagation or promote crack propagation along a path requiring, in at least one section of the bonding system, an amount of energy that is greater than a fracture energy needed to propagate a crack generally straight through a bond line of adhesive sans the indented solder element.

12. The method of claim 10, wherein the plurality of indentations are spaced generally evenly around the perimeter of the indented solder element.

13. The method of claim 10, wherein the plurality of indentations are concentrated in one or more areas of the solder element.

14. The method of claim 10, wherein each indentation has a depth that is between about 5% and about 50% of a solder element length or width.

15. The method of claim 10, wherein forming the plurality of indentations on the indented solder element is performed using a forming channel including at least one cast having a plurality of protrusions, wherein the protrusions are impressed on the solder shaped object while material of the solder shaped object is in a malleable state.

16. The method of claim 10, wherein the indented solder element is in contact with the first contact surface.

17. The method of claim 10, wherein the indented of solder element is in contact with the first contact surface and the second contact surface.

18. The method of claim 10, wherein the indented solder element is shaped generally spherical.

19. A method, to produce indented solder elements using a forming channel, comprising:
impressing a plurality of shaped solder objects, having malleable material, using a plurality of protrusions, yielding a plurality of indented solder elements; and
cooling the plurality of indented solder elements such that the malleable material is hardened.

20. The method of claim 19, wherein the forming channel comprises at least one cast having the plurality of protrusions in which at least one of the shaped solder objects is received prior to the impressing.
